(19) United States
(12) Patent Application Publication
(10) Pub. No.: US 2004/0083658 A1
(43) Pub. Date: May 6, 2004

(54) Method of making and utilizing a spill tolerant duplex receptacle

(76) Inventors: Gregg E. Laukuf, Bryan, OH (US); Mark E. Ramsey, Fort Wayne, IN (US)

Correspondence Address: Todd T. Taylor, TAYLOR & AUST, P.C., 142 S. Main St., P.O. Box 560, Avilla, IN, 46710, US

(21) Appl. No.: 10/689,889

(22) Filed: Oct. 21, 2003

Related U.S. Application Data
(60) Provisional application No. 60/420,416, filed on Oct. 22, 2002.

(51) Int. Cl. H01J 15/00; H05K 5/00; H01J 5/00; H02G 3/08; E04F 19/00

(52) U.S. Cl. 52/36.4; 174/50

(57) ABSTRACT

An office furniture system including at least one modular wall panel, a work surface attached to the at least one modular wall panel and a spill tolerant outlet coupled with the work surface. The spill tolerant outlet including a housing having a side and an opposite side, a plurality of electrical terminals accessible through the side and at least one fluid drain opening in the opposite side.

### CROSS REFERENCE TO RELATED APPLICATIONS

This is a non-provisional application based upon U.S. provisional patent application serial No. 60/420,416, entitled “DUPLEX RECEPTACLE WITH DRAIN HOLES”, filed Oct. 22, 2002.

### BACKGROUND OF THE INVENTION

1. Field of the Invention

The present invention relates to an electrical receptacle, and, more particularly, to a spill tolerant electrical outlet.

2. Description of the Related Art

The modern office environment often consists of large open areas or floor space that is divided into separate and distinct work areas by way of a modular wall panel system. Modular wall panels can be moved about with relative ease to change an office floor plan. Contained in modular wall panels are modular power distribution systems, which may include a wiring harness or wiring channel that is connected to a modular electrical device such as an electrical outlet. A wiring harness or channel typically includes a plurality of wires, which are associated with line, neutral and ground conductors of the power distribution system.

The distribution of electrical power in a modular power distribution system is accomplished by way of a plurality of connected, electrically pre-wired wiring harnesses that contain a plurality of power, neutral and ground lines. Connected to the wiring harness is a modular electrical outlet, which is electrically connected to a power source.

Work surfaces are often attached to, or even supported by, modular wall panels. Often a power distribution box is placed on the work surface and is interconnected with the power distribution system to provide easy access to electrical power on the work surface.

A work surface in an office or other working environment often contains a plethora of electronics equipment, paper reports and manuals, a telephone, lighting, and personal needs. Personal needs that are often located on the work surface include such items as beverage containers. If a beverage container or other fluid container is spilled on the work surface not only is there inconvenience but a potential hazard if the fluid enters an electrical outlet.

What is needed in the art is an electrical assembly that can tolerate fluid spills.

### SUMMARY OF THE INVENTION

The present invention provides a spill tolerant electrical outlet having an escape path for fluids, which may enter the electrical outlet.

The invention comprises, in one form thereof, an office furniture system including at least one modular wall panel, a work surface attached to the at least one modular wall panel and a spill tolerant outlet coupled with the work surface. The spill tolerant outlet includes a housing having a side and an opposite side, a plurality of electrical terminals accessible through the side and at least one fluid drain opening in the opposite side.

An advantage of the present invention is that fluid that enters the electrical outlet is directed to a drain hole through which the fluid can escape.

Another advantage is that the electrical outlet does not retain fluids therein.

Yet another advantage is that the electrical outlet of the present invention may be utilized in other applications.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 is a perspective view of an embodiment of a modular wall panel system including a spill tolerant outlet of the present invention;

FIG. 2 is a perspective view of an electrical assembly utilized in the system of FIG. 1;

FIG. 3 is a front view of an electrical outlet of the present invention utilized in the electrical assembly of FIG. 2 and in the modular wall panel system of FIG. 1;

FIG. 4 is an opposite side view of the electrical outlet of FIG. 3; and

FIG. 5 is a cross-sectional view of the electrical outlet of FIGS. 3 and 4 viewed from 5-5.

Corresponding reference characters indicate corresponding parts throughout the several views. The exemplification set out herein illustrates one preferred embodiment of the invention, in one form, and such exemplification is not to be construed as limiting the scope of the invention in any manner.

### DETAILED DESCRIPTION OF THE INVENTION

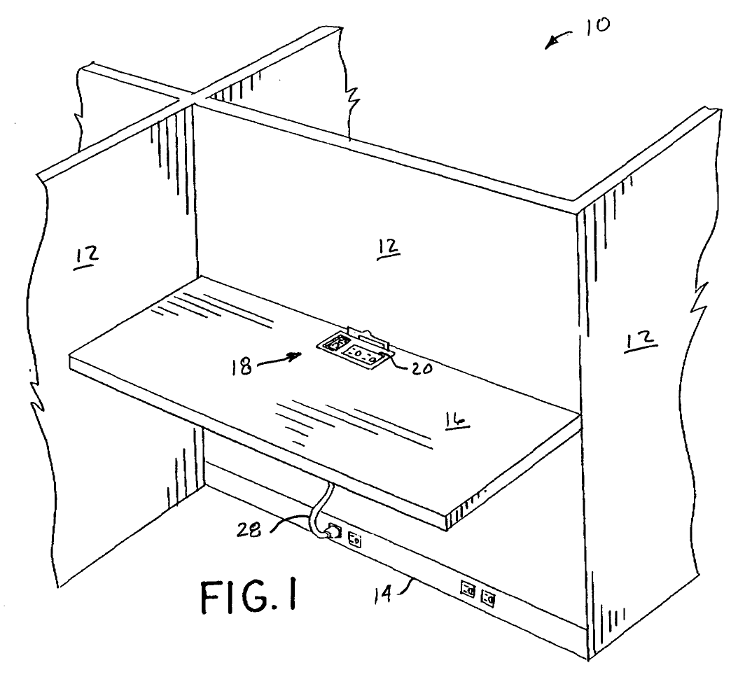

Referring now to the drawings, and more particularly to FIG. 1, there is shown an embodiment of the present invention contained in a modular wall panel system 10. Modular wall panel System 10 includes modular wall panels 12, wiring channel assembly 14, work surface 16, and electrical assembly 18. Modular wall panel system 10 is a typical system used in an office environment allowing the construction of work space modules within an open area of an office floor space.

On a portion of wall panel 12 there is a wiring channel assembly 14 wherein electrical power is distributed through wall panels 12.

Work surface 16 is connected to at least one wall panel 12 and is a substantially horizontal surface, which provides a work space area for a person in the office environment. There may be various items located on work surface 16 such as a computer system, telephone system, books, papers, and other equipment. In order to power the electronics in an office environment there is provided electrical assembly 18, which includes a telephone jack 22, a data jack 24, a lid 26, a cord 28 and a housing 29 that is inset into work surface 16.

Telephone jack 22 and data jack 24 are respectively connected with telephone and data circuits and thereby providing a convenient connection at work surface 16 to those services. Lid 26 sets in a recessed pocket and is positioned on the top of housing 29 by pulling up on lid 26 and then hinging lid 26 down over top of telephone jack 22 and data jack 24. Lid 26 has a opening 30 such that when lid 26 is closed access to electrical outlet 20 is still possible therethrough.

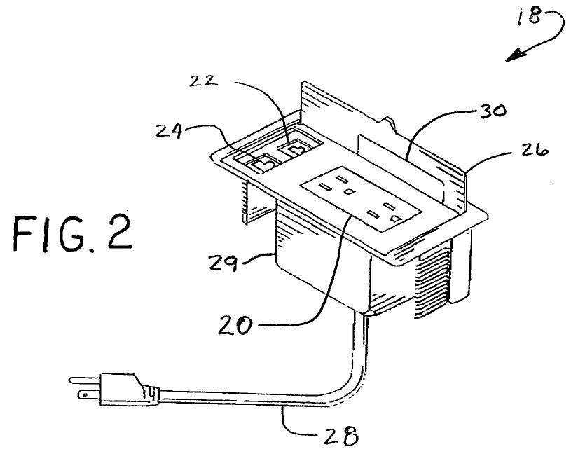

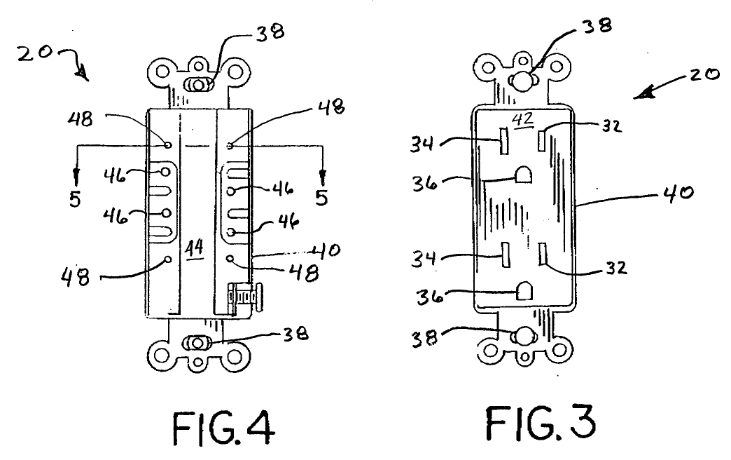

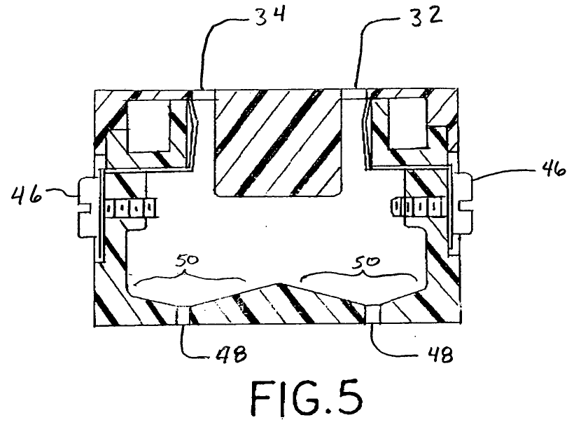

Now, additionally referring to FIGS. 2 through 5, there is shown electrical outlet 20 that includes power terminal opening 32, neutral terminal opening 34, ground terminal opening 36, attachment screws 38, housing 40, front side 42, back side 44, electrical feed connections 46, fluid escape openings 48 and sloped portions 50.

Electrical outlet 20 is positioned in electrical assembly 18 and is electrically connected to a power source by way of cord 28. Electrical outlet 20, as illustrated in FIGS. 1 and 2, is normally installed in a substantially horizontal manner with openings 32, 34 and 36 facing upward from horizontal surface 16. Housing 40 has a front side 42 and a back side 44, with front side 42 having openings 32, 34 and 36 therein. Opening 32 allows the power terminal of a standard 120 volt plug to enter therethrough to make electrical connection therein. In a like manner neutral terminal opening 34 and ground terminal opening 36 provide openings for the other two terminals of a standard electrical plug. Electrical feed connections 46 allow electrical wiring (not shown) to be connected to electrical outlet 20.

Fluid escape openings 48 are located along and through back side 44 in such a fashion as to allow fluid that may accumulate within electrical outlet 20 to escape therefrom. Openings 48 are large enough to allow the flow of fluid therethrough yet are sized small enough to prevent the entry of most insects therethrough. As can be seen in FIG. 5, sloped areas 50 may be included to further direct fluid toward fluid escape openings 48.

The purpose of fluid escape openings 48 is to allow electrical outlet 20 to be tolerant of spills of fluid that may enter through openings 32, 34 and 36 of front side 42. If fluid is spilled onto the top of electrical outlet 20 some fluid may enter through openings 32, 34 and 36. To prevent puddling or pooling of the fluid within electrical outlet 20 fluid escape openings 48 are positioned to remove fluid that enters therein. The goal is to provide an electrical outlet 20 that is tolerant to spills in such a manner as to prevent an electrical short circuit within electrical outlet 20.

Underwriter Laboratories “UL” includes a spill test section in safety standard UL-1363. One of the criteria of this standard is that spilled fluid is not to be allowed to create a conductive path between receptacle conductors within an electrical outlet such as electrical outlet 20. The goal is to maintain the dielectric integrity of the conductors after the injection of a measured amount of conductive fluid.

While the description of the invention illustrates a manner in which electrical outlet 20 may be manufactured, a standard duplex outlet can also be modified by the adding of fluid drain openings 48 through a back side 44 of electrical outlet 20. The positioning of fluid drain openings 48 is such that they are drilled, abraded, melted or otherwise made through back side 44 in portions of electrical outlet 20 that do not have conductive members proximate thereto. Additionally, the location of fluid escape openings 48 are such that they are at low spots in housing 40 so that accumulated fluid will be directed toward fluid escape openings 48. Even if the interior of housing 40 is relatively flat, appropriately placed fluid escape openings 48 will substantially drain fluid that enters through openings 32, 34 and 36 to prevent a conductive path from forming between conductors therein.

In use electrical outlet 20 is mounted horizontally in a work surface with front side 42 facing up. If a fluid spill occurs on work surface 16 fluid entering through openings 32, 34 and 36 will flow toward back side 44 and then escape through openings 48. Electrical outlet 20, even though being modified by the inclusion of fluid drain holes 48, can still be utilized in non-horizontal surfaces without compromising any electrical characteristic needed in that application.

Alternatively, drain holes 48 may be located along corners of housing 40 adjacent to back side 44.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. An office furniture system, comprising:
at least one modular wall panel;
a substantially horizontal component attached to at least one said modular wall panel; and
a spill tolerant outlet coupled with said substantially horizontal component, said spill tolerant outlet including:
a housing having a side and an opposite side;
a plurality of electrical terminals accessible through said side; and
at least one fluid drain opening in said opposite side.

2. The system of claim 1, wherein said substantially horizontal component is a work surface.

3. The system of claim 2, wherein said side of said spill tolerant outlet is substantially parallel with said work surface.

4. The system of claim 3, wherein said side of said spill tolerant outlet is directed in an upward direction.

5. The system of claim 4, further comprising at least one fluid direction portion which directs fluid toward a corresponding one of at least one said fluid drain opening.

6. The system of claim 1, wherein said at least one fluid drain opening is positioned in a portion of said opposite side that is most distant from said side.

7. A method of manufacturing a spill tolerant duplex outlet, comprising the steps of:
providing a duplex outlet having a receptor face and a housing connected to said receptor face, said housing having a side opposite said receptor face; and
adding at least one hole in said side.

8. The method of claim 7, further comprising the step of determining at least one location in said housing in which fluid will gather.

9. The method of claim 8, wherein at least one said hole is placed through said housing proximate to said at least one location.

10. The method of claim 9, wherein said at least one hole is made by one of drilling, melting and abrading.

11. The method of claim 7, further comprising the step of orienting said duplex outlet such that said receptor face is upward and said side is downward.

12. A spill tolerant electrical outlet, comprising:
a housing having a side and an opposite side;
a plurality of electrical terminals accessible through openings in said side; and
at least one fluid drain opening in said opposite side.

13. The outlet of claim 12, wherein said opposite side has a profile that directs fluids toward said at least one fluid drain opening when said side is facing upward.

14. The outlet of claim 12, wherein said at least one fluid drain opening is four fluid drain openings, each fluid drain opening located substantially opposite one of said openings in said side.

15. A spill tolerant electrical assembly, comprising:
an enclosure; and
a spill tolerant electrical outlet mounted at least partially within said enclosure, said spill tolerant electrical outlet including:
a housing having a side and an opposite side;
a plurality of electrical terminals accessible through openings in said side; and
at least one fluid drain opening in said opposite side.

16. The assembly of claim 15, wherein said opposite side has a profile that directs fluids toward said at least one fluid drain opening when said side is facing upward.

17. The assembly of claim 15, wherein said at least one fluid drain opening is four fluid drain openings, each fluid drain opening located substantially opposite one of said openings in said side.
